(19) United States
(12) Patent Application Publication
(10) Pub. No.: US 2008/0302562 A1
(43) Pub. Date: Dec. 11, 2008

(54) PRINTED CIRCUIT BOARD

(75) Inventor: Nobuo Kasagi, Toyama (JP)

Correspondence Address: DARBY & DARBY P.C., P.O. BOX 770, Church Street Station, New York, NY, 10008-0770, US

(73) Assignee: SMK Corporation, Tokyo (JP)

(21) Appl. No.: 12/133,550

(22) Filed: Jun. 5, 2008

(30) Foreign Application Priority Data
Jun. 8, 2007 (JP) 2007-152497

(51) Int. Cl. H05K 1/03

(52) U.S. Cl. 174/258

(57) ABSTRACT

A circuit is printed on a circuit board material, which does not have a copper foil layer and does have a paper base material is impregnated with a resin, using an electroconductive coating material. The board material preferably is a paper phenol board material, wherein the paper base material is impregnated with phenol resin, on which a resist layer is formed and a circuit is printed on the resist layer using an electroconductive coating material.

### CROSS-REFERENCE TO RELATED APPLICATION

The present application claims priority from Japanese Patent Application No. 2007-152497, filed on Jun. 8, 2007, and is hereby incorporated by reference in its entirety herein.

### FIELD OF THE INVENTION

The present invention relates to a printed circuit board, wherein a circuit is printed using an electroconductive coating.

### BACKGROUND OF THE INVENTION

Printed circuit boards that have been widely employed in the past use a copper clad board, wherein a phenol board material, a glass epoxy board material, or the like is laminated with copper foil.

To form a wiring pattern on a board material of these types, an etching resist layer is formed in the portion at which it is desired for the copper foil to remain, and the copper foil in the other portions is removed by a chemical etching process.

Accordingly, various processes are required such as a process that prints the etching resist by screen printing or the like, a process that sets the resist using, for example, ultraviolet light, and a process that etches and strips the copper foil; therefore, there are problems in that, not only do these processes require a long time to perform, but the use of chemical agents incurs a high environmental burden and necessitates the processing of the discharged water.

Accordingly, the applicant of the present application diligently investigated whether it is possible to use an electroconductive coating material to form the wiring pattern.

As a result, it was found that copper foil is not needed if the wiring pattern is printed using an electroconductive coating material with excellent solderability as disclosed in, for example, Japanese Published Unexamined Patent Application No. 2006-28213 (“the '213 application”) which is incorporated by reference herein in its entirety.

### SUMMARY OF THE INVENTION

It is an object of the present invention to provide a low cost printed circuit board that can shorten the manufacturing process.

In a printed circuit board according to the present invention, a circuit is printed using an electroconductive coating material on a circuit board material that does not have a copper foil layer and is a paper base material impregnated with a resin.

The paper base material impregnated with resin is lower in cost than glass epoxy board material, wherein a cloth made of glass fibers is impregnated with an epoxy resin.

The resin with which the paper base material is impregnated may be an epoxy resin or a phenol resin. Paper phenol board material, wherein a paper base material is impregnated with a phenol resin, is lower in cost and is therefore preferable.

A feature of the present invention is that it uses board material that has a paper base material and does not have a copper foil layer.

The board material, when a paper base material is used, preferably has water absorption properties that are generally higher than those of a glass epoxy board but is a paper phenol board material with a low water absorption percentage in order to prevent migration. The impregnated material preferably reduces the water absorption percentage to less than approximately 1.5% (wt %), and more preferably has a water absorption percentage of less than 1.0%

If a typical paper phenol board material with a water absorption percentage of approximately 1.5-2.5% is used. If stronger antimigration properties are required, then a resist layer should be formed on the board material and the circuit should be printed thereon using an electroconductive coating material.

Here, printing a circuit has the meaning of forming a wiring pattern of an electronic circuit directly on a board material using a printing means such as screen printing or jet printing.

In the present invention, a conventional copper foil laminated board material is not used, and a wiring pattern is printed on an insulator using an electroconductive coating material; consequently, a chemical etching process is not needed, which makes it possible to use a board material, wherein a paper base material is impregnated with a resin, without the risk of chemicals being absorbed in water due to immersion in an etching solution; thus, the present invention is superior in that it obtains a low-cost printed circuit board and is less taxing on the environment to the extent that it does not use chemical agents.

In addition, not only is the etching process not needed, but a coating of a UV setting film, such as an etching resist, is also not needed, which makes it possible to shorten the manufacturing process and to reduce intermediate inventory commensurately.

Superior antimigration properties can be obtained if a resist layer is formed on a board material wherein a paper base material is impregnated with a resin, and then a wiring pattern is printed with an electroconductive coating material.

### BRIEF DESCRIPTION OF THE DRAWINGS

The invention will become more readily apparent from the Detailed Description of the Invention, which proceeds with reference to the drawings, in which:

FIG. 1 shows an external view wherein the solder on the wiring pattern P-1 has been reflowed.

FIG. 2 shows the wiring pattern P-2 that was evaluated for its migration properties.

### DETAILED DESCRIPTION OF THE PREFERRED EMBODIMENTS

A printed circuit board according to the present invention can be adapted to various electronic boards; however, a present working example evaluated as an exemplary case features a printed circuit board used as a remote control board to remotely operate an electrical or electronic device, as explained below.

Two types of materials were prepared as paper phenol board materials, wherein a paper base material is impregnated with a phenol resin: board material A with a thickness of 1.6 mm and an absorption percentage of 2.0% (for example, PS-1131 made by Risho Kogyo Co., Ltd. of Tokyo, Japan), and board material B with a thickness of 1.6 mm and an absorption percentage of 0.8% (for example, PS-1143S made by Risho Kogyo Co., Ltd. of Tokyo, Japan)

As board materials having a paper base material is impregnated with resin, it is easy to obtain paper epoxy board material that is impregnated with an epoxy resin in addition to paper phenol board material; however, paper phenol board material is generally lower in cost.

In either case, in the present invention, copper foil is not needed and there is no chemical etching process; therefore, there is no risk that chemicals will be absorbed in water as a result of immersing the board in an aqueous solution, and it is possible to employ a board material that uses a paper base material.

A base material AR was prepared by coating one side of a base material A with a resist layer (for example, FINEDEL DSR-330R14-13 resist made by Tamura Corporation of Tokyo, Japan).

The resist layer was formed by spray coating the abovementioned resist coating material using a spray gun so that the thickness of the layer reached approximately 70-80 μm in the wet state, leveling the layer by leaving it at room temperature for 2-3 min, and then drying it for approximately 20 min at 70°-80° C.

Various coating materials, such as an epoxy coating material and acrylic coating material, can be used as the resist coating material provided that they have good adhesion properties with respect to the paper base material, e.g., paper phenol board base material and paper epoxy board base material, and good heat resistance properties such that they can withstand the temperature of the reflow oven.

Furthermore, in the present working example, a two-liquid type epoxy solder resist coating material was used.

The wiring pattern was screen printed using the electroconductive coating material 3 on the board base materials A, AR, and B.

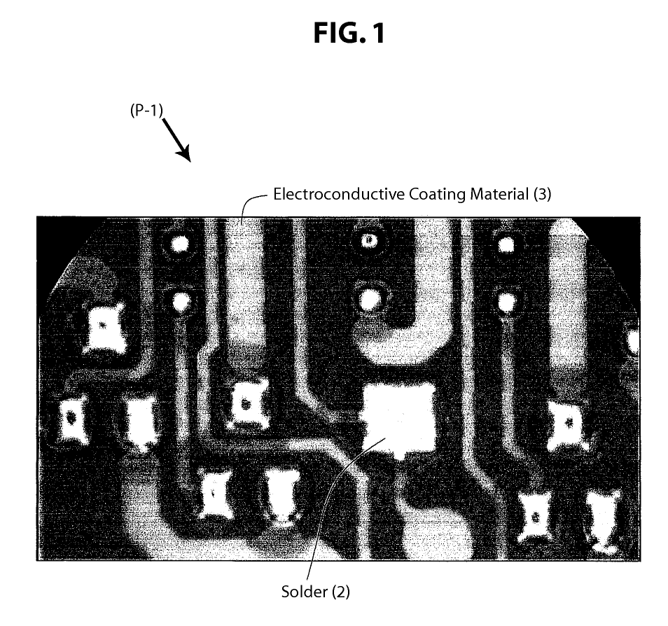

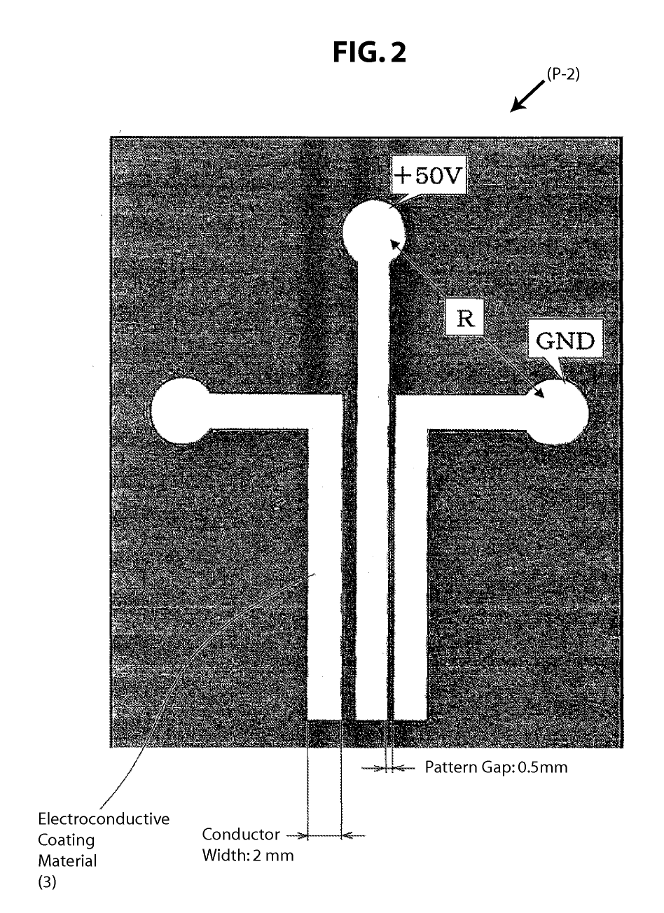

A wiring pattern P-1 (FIG. 1) for evaluating the wettability and the bonding strength of the reflow solder, and a wiring pattern P-2 (FIG. 2) for testing and evaluating migration (testing and evaluating ion migration) were fabricated.

The electroconductive coating material used in the evaluation is made by Maxell Hokuriku Seiki, Ltd. of Toyama, Japan, and is manufactured by mixing Ag-coated Ni powder and Ag powder, and mixing oleic acid and an organic solvent, i.e., butyl carbitol, using phenol resin as a binder. This coating material is further described in the '213 application.

After the wiring pattern was screen printed using the electroconductive coating material, a drying oven was used to dry the board material for approximately 30 min at 160° C.

FIG. 1 shows an external view of the wiring pattern P-1 after cream solder 2 was printed on the wiring pattern P-1 using a lead-free solder (for example, M705 made by Senju Metal Industry Co., Ltd. of Tokyo, Japan), and then reflowed in a reflow oven (for example, 1812 EXL-N2/UL made by Heller Industries, Inc. of Florham Park, N.J.).

The reflow soldering conditions were to preheat the oven to 150°-190° C., and then reflow the solder at 230°-240° C.

As a result, good solder wettability was exhibited.

When pressure was applied to the side faces of the solder mounted chip part, the paper phenol and the electroconductive coating material peeled apart at their contact surfaces, and the solder bonding strength was sufficient.

Furthermore, there was no problem with quality as long as the soldering strength of the chip part was 10 N/mm² or greater; based on this standard, when 6.4 N or greater were needed for the case of the wiring pattern P-1, the peeling strength was found to be satisfactory at 8.5-25.5 N.

The solder used in the present test and evaluation was a three-element lead-free solder of the Sn—Ag—Cu type, but the present invention is not particularly limited thereto as long as the solder is a reflow solder; furthermore, the Sn—Pb type solder widely employed in the past may be used.

The wiring pattern P-2 was subject to an applied voltage test for 850 hours at 60° C., 95% humidity, and 50 VDC; as a result, the A material without the resist layer shown in FIG. 2 exhibited an insulation resistance R of less than 100 MΩ, which was higher than that of the other A material; furthermore, the resistance of the AR material with the resist layer exceeded 100 MΩ, i.e., 100 MΩ or greater.

As an antimigration measure, it is preferable to use a paper phenol board material with a small absorption percentage of less than approximately 1.5% (wt %); furthermore, in cases where a typical paper phenol board material with an absorption percentage of approximately 1.5-2.5% was used, or where stronger antimigration properties were required, it was found that it is preferable to form the resist layer on the board material and print the circuit using the electroconductive coating material thereon.

1. A printed circuit board, comprising:
a circuit printed on a circuit board material, the circuit board material having no copper foil layer and including a paper base material impregnated with a resin, the circuit comprising an electroconductive coating material.

2. A printed circuit board according to claim 1, wherein
the board material is a paper phenol board material comprising a paper base material impregnated with phenol resin.

3. A printed circuit board according to claim 1, wherein
a resist layer is formed on the board material and a circuit is printed thereon using the electroconductive coating material.

4. A printed circuit board according to claim 2, wherein
a resist layer is formed on the board material and a circuit is printed thereon using the electroconductive coating material.
